(19) United States
(12) Patent Application Publication
(10) Pub. No.: US 2008/0153194 A1
(43) Pub. Date: Jun. 26, 2008

(54) Method for manufacturing image sensor

(76) Inventor: Seong Hee JEONG, Namdong-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/929,865

(22) Filed: Oct. 30, 2007

(30) Foreign Application Priority Data
Dec. 23, 2006 (KR) 10-2006-0133250

(51) Int. Cl. H01L 31/18

(52) U.S. Cl. 438/70; 257/E31.127

(57) ABSTRACT

A method for manufacturing an image sensor is provided. An interlayer insulating layer can be formed on a semiconductor substrate including a metal line, and a pad can be formed on the interlayer insulating layer. An insulating layer can be formed on the interlayer insulating layer and the pad, and a passivation layer can be formed on the insulating layer. A color filter layer can be formed on the passivation layer, and a planarization layer can be formed on the color filter layer. A microlens can be formed on the planarization layer, and a photoresist layer pattern exposing a portion of the passivation layer over the pad can be formed on the microlens. The pad can then be exposed by using the photoresist layer pattern as a mask, and the photoresist layer pattern can be removed.

### CROSS-REFERENCE TO RELATED APPLICATION

The present application claims the benefit under 35 U.S.C. §119 of Korean Patent Application No. 10-2006-0133250, filed Dec. 23, 2006, which is hereby incorporated by reference in its entirety.

### BACKGROUND

In general, image sensors are semiconductor devices that convert an optical image into an electrical signal. Image sensors can be classified into charge coupled device (CCD) image sensors and complementary metal oxide semiconductor (CMOS) image sensors.

CMOS image sensors typically include a photodiode for detecting emitted light and a CMOS logic circuit for processing the detected light as an electrical signal. The photosensitivity of the image sensor generally improves as the quantity of light received by the photodiode increases.

The fill factor of an image sensor is the ratio of the area of the photodiode to the entire area of the image sensor. In order to increase the photosensitivity of an image sensor, the fill factor can be increased or a focusing technology can be used. The focusing technology involves changing an optical path of light incident onto a region excluding the photodiode so that incident light is focused on the photodiode.

An example of the focusing technology includes forming a microlens. In detail, a convex microlens is formed of a material with excellent light transmittance on the photodiode. The microlens serves to refract a path of incident light, so that a larger amount of light can be emitted to the photodiode region.

Light parallel to an optical axis of the microlens is refracted by the microlens such that it is focused at a predetermined position of the optical axis.

In the related art, when manufacturing a CMOS image sensor, a metal pad is exposed first, and then a color filter layer is formed.

However, since the pad is exposed to a development solution of a photoresist layer during the subsequent process of forming the color filter layer, the metal pad becomes corroded.

Also, when a microlens is formed in the related art, the microlens often becomes undesirably separated when the photoresist layer is removed.

Thus, there exists a need in the art for an improved method of manufacturing an image sensor.

### BRIEF SUMMARY

Embodiments of the present invention provide a method for manufacturing an image sensor capable of inhibiting corrosion of a metal pad.

Embodiments also provide a method for manufacturing an image sensor capable of inhibiting undesired separation of a microlens during formation of the microlens.

In an embodiment, a method for manufacturing an image sensor can include: forming an interlayer insulating layer on a semiconductor substrate including a metal line; forming a pad on the interlayer insulating layer; forming an insulating layer on the interlayer insulating layer and the pad; forming a passivation layer on the insulating layer; forming a color filter layer on the passivation layer; forming a planarization layer on the color filter layer; forming a microlens on the planarization layer; forming a photoresist layer pattern exposing a portion of the passivation layer over the pad; exposing the pad by using the photoresist layer pattern as a mask; and removing the photoresist layer pattern.

The details of one or more embodiments are set forth in the accompanying drawings and the detailed description below. Other features will be apparent to one skilled in the art from the detailed description, the drawings, and the appended claims.

### BRIEF DESCRIPTION OF THE DRAWINGS

FIGS. 1 to 7 are cross-sectional views showing a method for manufacturing an image sensor according to an embodiment of the present invention.

### DETAILED DESCRIPTION

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

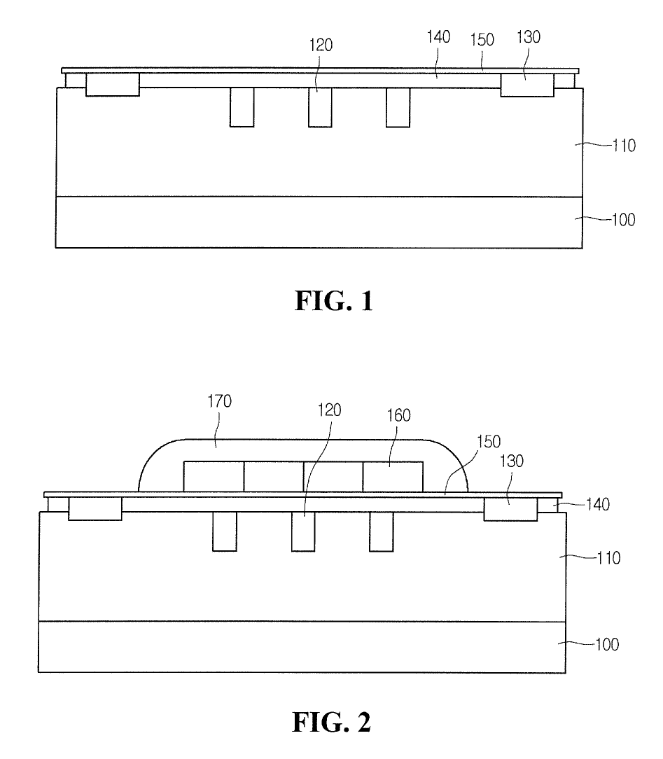

Referring to FIG. 1, metal lines 120 can be formed in an interlayer insulating layer 110 on a semiconductor substrate 100.

Here, a plurality of light sensing devices, for example, photodiodes (not shown) and/or various transistors (not shown) can be formed on the substrate 100.

In an embodiment, the interlayer insulating layer 110 can have a multi-layered structure. In another embodiment, a light blocking layer (not shown) can be formed after one interlayer insulating layer is formed, and then another interlayer insulating layer can be formed on the light blocking layer. The light blocking layer can be used to prevent light from being incident onto a region other than the photodiode (not shown).

Then, pads 130 can be formed on the interlayer insulating layer 110, and an insulating layer 140 can be formed on the semiconductor substrate 100 including the pads 130.

The insulating layer 140 can be formed of any suitable material known in the art, for example, an oxide material such as tetraethyl orthosilicate (TEOS). The insulating layer 140 can be formed to a thickness about 50 Å to about 200 Å. A thickness in this range can help facilitate exposure of the pad 130 in a subsequent process.

Then, a passivation layer 150 can be formed on the insulating layer 140.

The passivation layer 150 can be used to protect a device from moisture and scratches. In an embodiment, the passivation layer 150 can be formed by applying an organic layer and performing a hard-curing process on the organic layer. The organic layer can be applied, for example, to a thickness of about 50 nm or less. An organic material having excellent transparency within the visible spectrum can help improve the profile and evenness of a color filter layer 160 that may be formed in a subsequent process. In one embodiment, the passivation layer 150 can be formed by using a thermoplastic resin.

Referring to FIG. 2, a color filter layer 160 can be formed above the semiconductor substrate 100 on the passivation layer 150.

In an embodiment, to form the color filter layer 160, a dyeable resist (not shown) can be applied on the insulating layer 140, and exposure and development processes can be performed to form color filters (R, G, and B).

Each of the color filters (R, G, and B) can be formed by applying a corresponding photoresist material to a thickness of about 1 μm to about 5 μm. The photoresist material can then be patterned by a photolithography process using separate masks. Accordingly, the color filter layer 160 filtering light in each wavelength band can be formed as a single layer.

Then, a planarization layer 170 can be formed on the color filter layer 160. In an embodiment, the planarization layer 170 can be formed by depositing a silicon nitride layer on the entire surface of the semiconductor substrate 100 including the color filter layer 160 to improve reliability and inhibit penetration of moisture or heavy metals.

Since optical transmission is important in the image sensor, the thickness of the planarization layer 170 can be, for example, from 1,000 Å to about 6,000 Å. Using a planarization layer 170 with a thickness in that range can help inhibit thin-film interference.

In the related art, the pad is exposed before the color filter layer is formed in a manufacturing process of an image sensor, so the pad is exposed to a development solution of a photoresist layer during the process of forming the color filter layer. The development solution of the photoresist layer causes corrosion of the metal pad in the related art.

However, according to embodiments of the present invention, since the pad 130 can be exposed after a microlens is formed, corrosion of the pad can be inhibited.

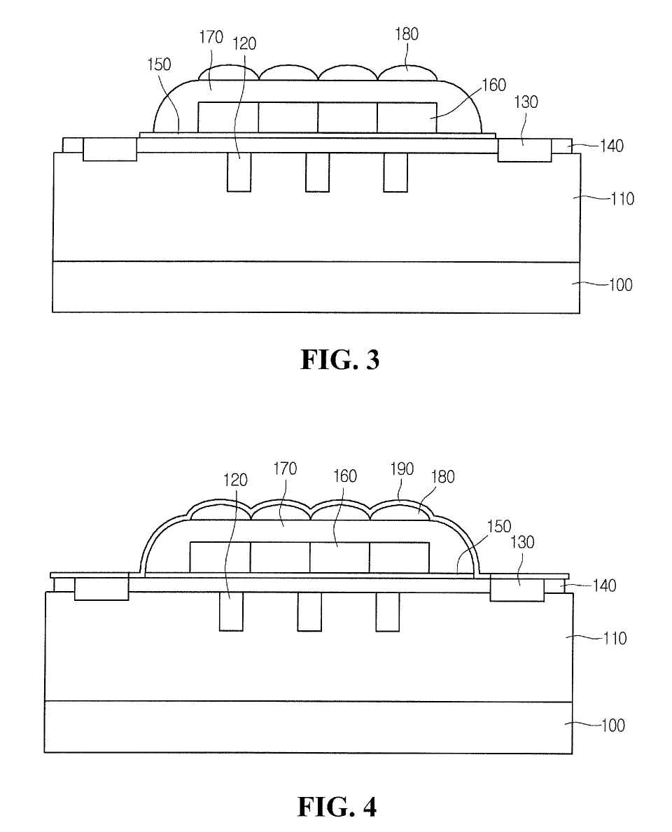

Referring to FIG. 3, a microlens 180 can be formed on the planarization layer 170.

In an embodiment, a photoresist (not shown) for the microlens 180 can be applied on the entire surface of the semiconductor substrate 100 including the planarization layer 170.

The photoresist can be selectively patterned by exposure and development processes using a microlens mask (not shown) to form a microlens pattern (not shown). The photoresist for the microlens 180 can be any suitable photoresist known in the art, for example, a negative photoresist or a positive photoresist.

The semiconductor substrate 100 including the microlens pattern (not shown) can undergo a heat treatment on a hot plate (not shown) at a temperature of about 150° C. or higher to reflow the microlens pattern to form the microlens 180 with a hemispherical shape. For example, the reflow can be made at about 300° C. to about 700° C.

In an embodiment, a portion of the passivation layer 150 exposed by the planarization layer 170 can be removed during the exposure, development, and reflow processes of the microlens 180.

Referring to FIG. 4, a flexible photoresist layer 190 can be formed on the entire surface of the semiconductor substrate 100 including the microlens 180.

The flexible photoresist layer 190 can be formed of any suitable material known in the art, for example, a flexible resist such as “SLIM”.

In the related art, the microlens often becomes undesirably separated when a photoresist layer is removed.

However, according to embodiments of the present invention, since the flexible photoresist layer 190 can be formed on the microlens 180, the microlens 180 can be inhibited from being damaged when a photoresist layer is removed. Accordingly, the undesired separation of the microlens 180 can be inhibited, such that the shape and clarity of the surface of the microlens 180 can be improved.

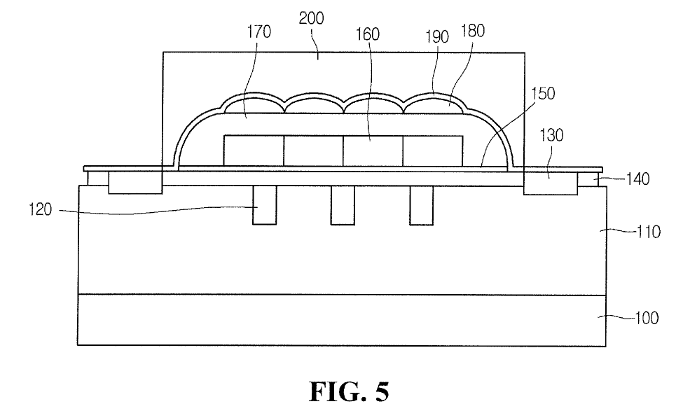

Referring to FIG. 5, a photoresist layer pattern 200 can be formed on the semiconductor substrate 100 including the microlens 180, exposing a portion of the flexible photoresist layer 190 over the pad 130.

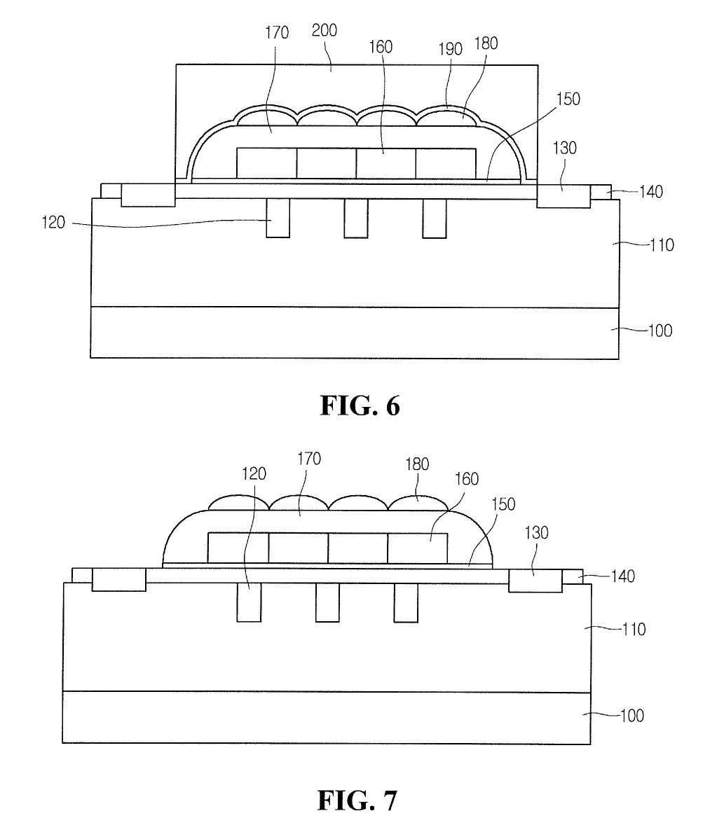

Referring to FIG. 6, the pad 130 can be exposed by using the photoresist layer pattern 200 as a mask.

Referring to FIG. 7, the photoresist layer pattern 200 can then be removed from the semiconductor substrate 100. In an embodiment, the flexible photoresist layer 190 can be removed together with the photoresist layer pattern 200 to inhibit the microlens 180 from being damaged.

According to embodiments of the present invention, corrosion of a pad can be inhibited since the pad 130 can be exposed after forming the microlens.

Furthermore, in embodiments of the present invention, the microlens 180 can be inhibited from being damaged when the photoresist layer for exposing the pad region is removed since the flexible photoresist layer 190 can be formed on the microlens. Accordingly, undesired separation of the microlens can be inhibited, thereby improving the shape and clarity of the surface of the microlens 180.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing an image sensor, comprising:
forming an interlayer insulating layer on a semiconductor substrate including a metal line;
forming a pad on the interlayer insulating layer;
forming an insulating layer on the semiconductor substrate including the interlayer insulating layer and the pad;
forming a passivation layer on the insulating layer;
forming a color filter layer on the passivation layer;
forming a planarization layer on the color filter layer;
forming a microlens on the planarization layer;
forming a photoresist layer pattern on the microlens exposing a portion of the passivation layer over the pad;
exposing the pad using the photoresist layer pattern as an etch mask; and
removing the photoresist layer pattern.

2. The method according to claim 1, further comprising forming a flexible photoresist layer on the microlens before forming the photoresist pattern on the microlens.

3. The method according to claim 2, wherein the flexible photoresist layer is removed when removing the photoresist layer pattern.

4. The method according to claim 2, wherein the flexible photoresist layer comprises a flexible resist.

5. The method according to claim 2, wherein the flexible photoresist layer comprises SLIM.

6. The method according to claim 1, wherein the insulating layer comprises tetraethyl orthosilicate (TEOS).

7. The method according to claim 1, wherein the insulating layer has a thickness of between about 50 Å and about 200 Å.

8. The method according to claim 1, wherein the passivation layer comprises a thermoplastic resin.

9. The method according to claim 1, wherein forming the passivation layer comprises:
applying an organic layer on the insulating layer; and
performing a hard-curing process on the organic layer.

10. The method according to claim 9, wherein the organic layer has a thickness of at most about 50 nm.

11. The method according to claim 1, wherein forming the passivation layer comprises depositing a silicon nitride layer on the insulating layer.

12. The method according to claim 1, wherein the planarization layer has a thickness of about 1,000 Å to about 6,000 Å.

13. The method according to claim 1, further comprising removing a portion of the passivation layer exposed by the planarization layer when forming the microlens.

14. The method according to claim 13, wherein forming the microlens comprises:
applying a photoresist to the planarization layer;
patterning the photoresist using a microlens mask to form a microlens pattern; and
performing a heat treatment to reflow the microlens pattern to form the microlens.

15. The method according to claim 14, wherein the heat treatment is performed at a temperature of at least about 150° C.

16. The method according to claim 14, wherein the heat treatment is performed at a temperature of about 300° C. to about 700° C.

17. The method according to claim 1, wherein the color filter layer is formed on the passivation layer over a region of the semiconductor substrate.

18. The method according to claim 1, wherein the pad comprises a metal material.
